(19) United States
(12) Patent Application Publication
(10) Pub. No.: US 2012/0108003 A1
(43) Pub. Date: May 3, 2012

(54) METHOD FOR PRODUCING A SOLAR CELL

(75) Inventors: Bernd Bitnar, Bannewitz (DE); Lars Oberbeck, Dresden (DE); Ralf Luedemann, Weissenborn (DE)

(73) Assignee: SOLARWORLD INNOVATIONS GMBH, Freiberg (DE)

(21) Appl. No.: 13/287,212

(22) Filed: Nov. 2, 2011

(30) Foreign Application Priority Data
Nov. 2, 2010 (DE) 10 2010 060 303.1

(51) Int. Cl. H01L 31/18

(52) U.S. Cl. 438/98; 257/E31.124

(57) ABSTRACT

In various embodiments, a method for producing a solar cell is provided. In accordance with the method, through-holes may be formed in a solar cell substrate having the basic doping of a first conduction type. Furthermore, predetermined surface regions of a first surface of the solar cell substrate which include at least one portion of the through-holes may be highly doped with a second, opposite conduction type; and simultaneously or subsequently other surface regions of the first surface are lightly doped with the second conduction type. Furthermore, first and second metallic contacts may subsequently be formed in such a way that the second metallic contacts are electrically isolated from the first metallic contacts.

### CROSS-REFERENCE TO RELATED APPLICATION

This application claims priority to German Patent Application Serial No. 10 2010 060 303.1, which was filed Nov. 2, 2010, and is incorporated herein by reference in its entirety.

### TECHNICAL FIELD

This disclosure relates to a method for producing a solar cell.

### BACKGROUND

A so-called Metal Wrap Through (MWT) solar cell has the contacts for the n-type region (n-doped region) and the p-type region (p-doped region) usually on the rear side of the silicon wafer. For this purpose, there are a number of holes through the silicon water through which a metallic contact establishes the electrical connection between the front contact fingers and the rear-side busbar. The metallic through-contacts are insulated from the base of the solar cell in the holes. This is typically done by the emitter being formed on the inner walls of the holes. In the same way, the soldering contact on the rear side is insulated from the base of the solar cell by the emitter. A conventional MWT solar cell is described in DE 698 37 143 T2, DE 692 16 502 T2, EP 2 068 369 A1 or DE 10 2009 047 778 A1.

A so-called solar cell having a selective emitter (also designated as SE solar cell hereinafter) utilizes regions doped to different extents below the contact fingers and in the region between the contacts. In this case, the doping below the contacts is high, in order to achieve a low contact resistance, and the doping between the fingers is lower, in order to minimize recombinations of the charge carriers.

Furthermore, DE 101 50 040 A1 describes HF/fluoride-free etching and doping media suitable both for etching inorganic layers and for doping an underlying layer.

Furthermore, DE 699 15 317 T2 describes a self-aligning method for the production of a selective emitter and the metallization in a solar cell.

Various methods are known as to how a solar cell with a selective emitter may be produced, wherein an intermediate step is present involving the formation of a so-called homogenous emitter in the context of the production process. Thus, by way of example, in the case of a laser doping (University of Stuttgart, MANZ AG), whole-area (high-impedance) diffusion is provided, with a subsequent selective drive-in of phosphorus doping atoms from phosphorus glass by means of a laser. In a different process, which is also designated as an etching-back process, a (low-impedance) diffusion is provided, with subsequent application of an etching mask and defined etching-back of phosphorus glass in regions between respective contact fingers of the solar cell. The etching mask is subsequently removed. In yet another process, which is also designated as the Laser Chemical Process, a whole-area (high-impedance) diffusion is provided, with subsequently selective additional doping by means of a laser in a phosphoric acid jet.

### SUMMARY

In various embodiments, a method for producing a solar cell is provided. In accordance with the method, through-holes may be formed in a solar cell substrate having the basic doping of a first conduction type. Furthermore, predetermined surface regions of a first surface of the solar cell substrate which include at least one portion of the through-holes may be highly doped with a second, opposite conduction type; and simultaneously or subsequently other surface regions of the first surface are lightly doped with the second conduction type. Furthermore, first metallic contacts may subsequently be formed at least in one portion of the predetermined regions in at least one portion of the through-holes and in first regions of a second surface of the solar cell substrate, which lies opposite the first surface of the solar cell substrate. Finally, second metallic contacts may be formed in second regions on the second surface in such a way that the second metallic contacts are electrically isolated from the first metallic contacts.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1 shows a flowchart illustrating a method for producing a solar cell in accordance with various embodiments;

FIG. 2 shows a flowchart illustrating a method for producing a solar cell in accordance with one implementation of various embodiments;

FIG. 3 shows a flowchart illustrating a method for producing a solar cell in accordance with another implementation of various embodiments;

FIG. 4 shows a flowchart illustrating a method for producing a solar cell in accordance with another implementation of various embodiments; and

FIG. 5 shows a flowchart illustrating a method for producing a solar cell in accordance with another implementation of various embodiments.

### DETAILED DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface, may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

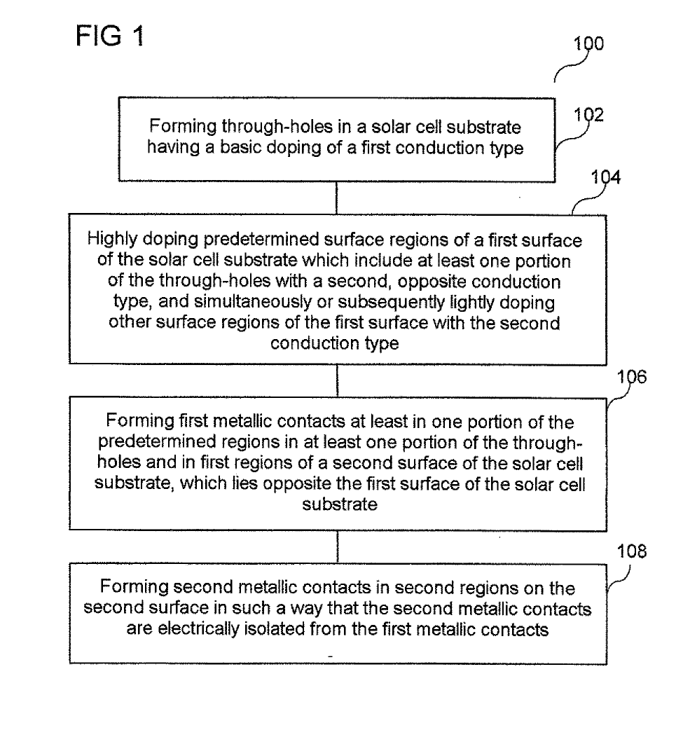

FIG. 1 shows a flowchart illustrating a method 100 for producing a solar cell (for example a Metal Wrap Through (MWT) solar cell) in accordance with various exemplary embodiments.

In accordance with the method, in 102, through-holes may be formed in a solar cell substrate having the basic doping of a first conduction type. The solar cell substrate may have at least one photovoltaic layer (for example as part of a layer structure including one or a plurality of layers). The at least one photovoltaic layer may include or consist of a semiconductor material (such as, for example silicon), a compound semiconductor material (such as, for example, a III-V compound semiconductor material such as GaAs, for example), a II-VI compound semiconductor material (such as CdTe, for example), or a I-III-V compound semiconductor material (such as CuInS₂, for example). In various embodiments, the at least one photovoltaic layer may include or consist of an organic material. In various embodiments, the silicon may include or consist of monocrystalline silicon, polycrystalline silicon, amorphous silicon, and/or microcrystalline silicon. The at least one photovoltaic layer may include or consist of a junction structure such as, for example, a pn junction structure, a pin junction structure, a Schottky-like junction structure, and the like.

In various embodiments, the basic doping in the solar cell substrate may have a doping concentration (for example of a doping of the first conduction type) in a range of approximately 10¹³ cm⁻³ to 10¹⁸ cm⁻³, for example in a range of approximately 10¹⁴ cm⁻³ to 10¹⁷ cm⁻³, for example in a range of approximately 10¹⁵ cm⁻³ to 10¹⁶ cm⁻³.

In various embodiments, the through-holes may have a cylindrical form having a circular or elliptical cross section. In other embodiments, however, the through-holes may have a tapered course through the solar cell substrate (illustratively therefore a conical form), wherein the opening on the emitter side of the solar cell substrate may be smaller than the opening on the rear side of the solar cell substrate. Furthermore, the through-holes within a solar cell substrate may have the same or different dimensions. In various embodiments, the through-holes may have a diameter in a range of approximately 10 μm to 500 μm, for example a diameter in a range of approximately 20 μm to 200 μm, for example a diameter in a range of approximately 50 μm to 100 μm.

The solar cell substrate may be produced from a solar cell wafer and may have, for example, a round form such as, for example, a circular form or an elliptical form or a polygonal form such as, for example, a square form. In various embodiments, however, the solar cells of the solar module may also have a non-square form. In these cases, the solar cells of the solar module may be formed, for example, by separating (for example cutting) and thus dividing one or more solar cell(s) (also designated as standard solar cell in terms of their form) to result in a plurality of non-square or square solar cells. In various embodiments, provision may be made in these cases for performing adaptations of the contact structures in the standard solar cell; by way of example, rear-side transverse structures may additionally be provided.

In various embodiments, the solar cell 100 may have the following dimensions: a width in a range of approximately 10 cm to approximately 50 cm, a length in a range of approximately 10 cm to approximately 50 cm, and a thickness in a range of approximately 100 μm to approximately 300 μm.

In 104, predetermined surface regions of a first surface of the solar cell substrate which include at least one portion of the through-holes (i.e. one through-hole, a plurality of through-holes or all through-holes) may be highly doped with a second, opposite conduction type; and simultaneously or subsequently other surface regions of the first surface may be lightly doped with the second conduction type.

In various embodiments, the predetermined surface regions may be doped with a suitable dopant such as phosphorus, for example. In various embodiments, the second conduction type may be a p conduction type, and the first conduction type may be an n conduction type. Alternatively, in various embodiments, the second conduction type may be an n conduction type, and the first conduction type may be a p conduction type.

In various embodiments, the predetermined surface regions of the first surface of the solar cell substrate may be highly doped with dopant for doping with the second conduction type with a surface doping concentration in a range of approximately 10¹⁸ cm⁻³ to approximately 10²² cm⁻³, for example with a doping concentration in a range of approximately 10¹⁹ cm⁻³ to approximately 10²² cm⁻³, for example with a doping concentration in a range of approximately 10²⁰ cm⁻³ to approximately 2*10²¹ cm⁻³. The sheet resistance in the highly doped regions having the second conduction type is in the range of approximately 10 ohms/sq to approximately 80 ohms/sq, for example in a range of approximately 20 ohms/sq to approximately 60 ohms/sq, for example in a range of approximately 25 ohms/sq to approximately 40 ohms/sq.

Furthermore, in various embodiments, the other surface regions of the first surface having the second conduction type may be lightly doped with dopant for doping with the second conduction type with a surface doping concentration in a range of approximately 10¹⁸ cm⁻³ to approximately 2*10²¹ cm⁻³, for example with a doping concentration in a range of approximately 10¹⁹ cm⁻³ to approximately 10²¹ cm⁻³, for example with a doping concentration in a range of approximately 5*10¹⁹ cm⁻³ to approximately 5*10²⁰ cm⁻³. The sheet resistance in the lightly doped regions having the same conduction type is in a range of approximately 60 ohms/sq to approximately 300 ohms/sq, for example in a range of approximately 80 ohms/sq to approximately 200 ohms/sq, for example in a range of approximately 100 ohms/sq to approximately 150 ohms/sq. In this way, illustratively a selective emitter is formed at least on the first surface of the solar cell substrate.

Furthermore, subsequently in 106 first metallic contacts may be formed at least in one portion of the predetermined regions in at least one portion of the through-holes and in first regions of a second surface of the solar cell substrate, which lies opposite the first surface of the solar cell substrate.

In various embodiments, the first metallic contacts may be formed from a metal or a metal alloy and may include or consist of, for example, silver, copper, aluminum, nickel, tin, titanium, palladium, tantalum, gold, platinum or any desired combination or alloy of these materials. The first metallic contacts illustratively form the electrical connection to the (selective) emitter on the first surface of the solar cell substrate.

Finally, in 108, second metallic contacts may be formed in second regions on the second surface in such a way that the second metallic contacts are electrically isolated from the first metallic contacts. The second metallic contacts, which may be formed from the same or a different metal or metal alloy relative to the first metallic contacts described above illustratively form the rear-side metallization of the solar cell to be formed.

In various embodiments, the process of forming the selective emitter may be restricted to the front side of the solar cell substrate or else relate to the doping in the holes and on the rear side of the solar cell substrate.

Various implementations of the exemplary embodiments described above are explained in greater detail below.

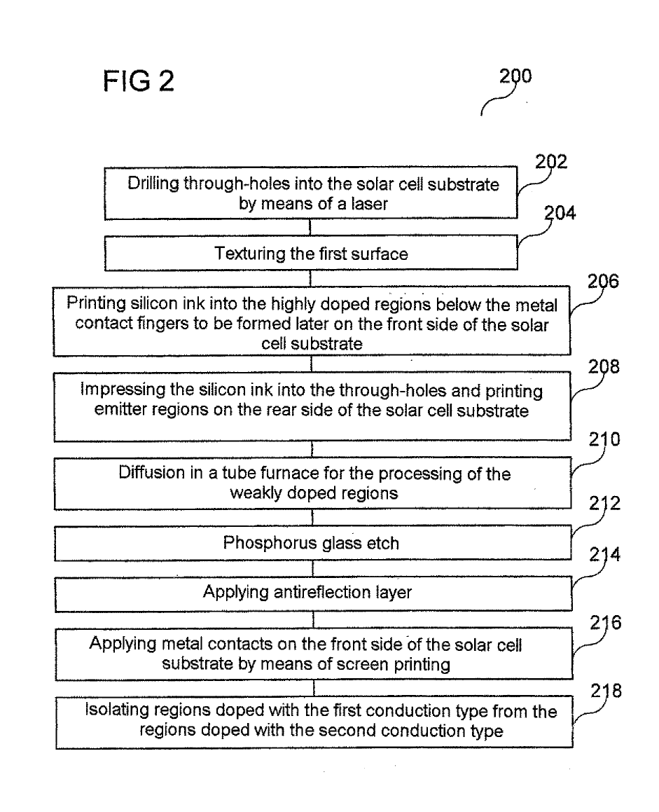

FIG. 2 shows a flowchart 200 illustrating a method for producing a solar cell in accordance with one implementation of various embodiments.

In accordance with this implementation, the selective emitter structure is generally produced by means of printing a structure composed of doped silicon ink. The selective emitter is formed in the subsequent diffusion step.

In detail, the process sequence in accordance with this implementation includes, for example:

In 202, for example by means of a laser, through-holes are drilled into the solar cell substrate (wherein metal contact fingers may already have been formed onto the solar cell substrate). In an alternative configuration, the through-holes may be formed by means of an etching process, alternatively or additionally by means of a laser.

Furthermore, in an optional process in 204 the surface, for example the emitter side surface (to put it another way the sun side of the solar cell to be formed), may be textured, for example by means of anisotropic etching in an alkaline solution or by means of etching in an acidic solution or by means of sawing V-trenches into the solar cell substrate on the first surface.

Subsequently, in 206, doped (typically doped with phosphorus) silicon ink may be printed into the highly doped regions below the metal contact fingers to be formed later on the front side (i.e. the first surface) of the solar cell substrate. The silicon ink may be doped for example with phosphorus with a doping concentration in a range of approximately 10¹⁸ cm⁻³ to approximately 10²² cm⁻³, for example with a doping concentration in a range of approximately 10¹⁹ cm⁻³ to approximately 5*10²¹ cm⁻³, for example with a doping concentration in a range of approximately 10²⁰ cm⁻³ to approximately 10²¹ cm⁻³.

Furthermore, in 208, the silicon ink may be impressed into the through-holes and it may also be printed onto the emitter regions of the rear side (i.e. of the second surface of the solar cell substrate) which have been or are electrically coupled to the silicon ink in the through-holes, such that an electrically conductive connection is formed between the emitter region on the emitter side of the solar cell substrate and the emitter regions on the rear side. Alternatively, it is possible to print these regions of the rear side by means of a suitable paste, for example a phosphorus-containing paste.

In 210, diffusion in a tube furnace for the processing of the weakly doped regions may be provided. The diffusion may be carried out for example at a temperature in a range of approximately 700° C. to approximately 1000° C., for example in a range of approximately 750° C. to approximately 950° C., for example in a range of approximately 800° C. to approximately 900° C., for example for a time duration in a range of approximately 3 minutes to approximately 120 minutes, for example in a range of approximately 10 minutes to approximately 60 minutes, for example in a range of approximately 15 minutes to approximately 45 minutes.

Subsequently, in 212, a phosphorus glass etch may be carried out in order to remove the phosphorus glass (for example phosphosilicate glass (PSG)), that has been formed in the context of the diffusion from the paste.

In 214, an antireflection layer (for example composed of silicon nitride or some other suitable material) may then be applied, for example by means of a CVD method, for example by means of a plasma-enhanced (PE) CVD method (PE-CVD), or by means of a PVD method, such as e.g. by means of sputtering.

In 216, on the rear side and the front side of the solar cell substrate, metal contacts (also designated as metal fingers) are formed, for example by means of the screen printing of a suitable metal-containing (for example silver-containing or aluminum-containing) paste, and the paste, and thus the metal, for example, is impressed into the through-holes. A contact firing step is used to fire the paste and thus the metal through the antireflection layer formed previously, whereby an electrical contact with the semiconductor surface (for example silicon surface) of the solar cell substrate is formed.

Finally, in 218, in this implementation, the regions doped with the first conduction type (for example n-doped) are isolated, to put it another way electrically insulated, from the regions doped with the second conduction type (for example p-doped), for example by one laser trench or a plurality of laser trenches being formed.

It should be pointed out that in various implementations, printing the doped silicon ink may optionally be restricted to the front side.

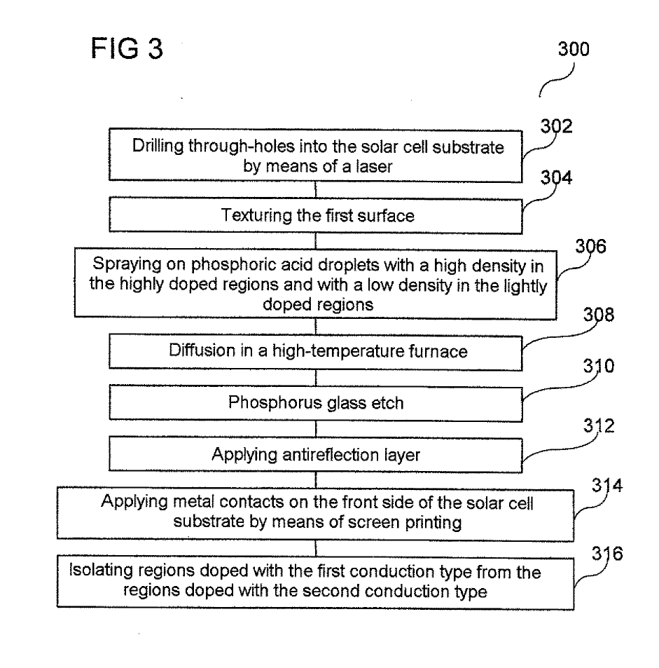

FIG. 3 shows a flowchart 300 illustrating a method for producing a solar cell in accordance with another implementation of various embodiments.

In accordance with this implementation, the selective emitter is generally produced by means of spraying on phosphoric acid droplets of different densities. Illustratively, in accordance with this implementation, after the processing of the through-holes and the texturing, an inhomogeneous covering of the solar cell substrate (for example wafer) with dopant is obtained by a dopant being dispensed. In the regions onto which the contact fingers are intended to be positioned later and also in the region of the through-holes, the density of the dopant is higher than in the intervening regions. During a subsequent heat treatment step, the dopant is driven into the solar cell substrate (for example wafer), the selective emitter being formed. Afterward, the antireflection layer is applied to the front side of the solar cell substrate and the metal contacts are processed.

In detail, the process sequence in accordance with this implementation includes, for example:

In 302, for example by means of a laser, through-holes are drilled into the solar cell substrate (wherein metal contact fingers may already have been formed onto the solar cell substrate). In an alternative configuration, the through-holes may be formed by means of an etching process, alternatively or additionally by means of a laser.

Furthermore, in an optional process in 304 the surface, for example the emitter side surface (to put it another way the sun side of the solar cell to be formed), may be textured, for example by means of anisotropic etching in an alkaline solution or by means of etching in an acidic solution or by means of sawing V-trenches into the solar cell substrate on the first surface.

In 306, in this implementation, phosphoric acid droplets are sprayed on with a high density in the highly doped regions and with a low density in the lightly doped regions. The highly doped regions may be situated on the front side and optionally also in the holes or on the rear side. What may be achieved by admixing a suitable wetting agent with the phosphoric acid is that the wetting p phosphorus solution is drawn by capillary forces into the through-holes, such that a very high doping may be achieved there. The droplets may be sprayed on with a high density in the highly doped regions in such a way that the highly doped regions are doped with a surface doping concentration in a range of approximately 10¹⁸ cm⁻³ to approximately 10²² cm⁻³, for example with a doping concentration in a range of approximately 10¹⁹ cm⁻³ to approximately 10²² cm⁻³, for example with a doping concentration in a range of approximately 10²⁰ cm⁻³ to approximately 2*10²¹ cm³. The sheet resistance in the highly doped regions having the second conduction type lies in a range of approximately 10 ohms/sq to approximately 80 ohms/sq, for example in a range of approximately 20 ohms/sq to approximately 60 ohms/sq, for example in a range of approximately 25 ohms/sq to approximately 40 ohms/sq.

The droplets may be sprayed on with a low density in the lightly doped regions in such a way that the lightly doped regions are doped with a surface doping concentration in a range of approximately 10¹⁸ cm⁻³ to approximately 2*10²¹ cm⁻³, for example with a doping concentration in a range of approximately 10¹⁹ cm⁻³ to approximately 10²¹ cm⁻³, for example with a doping concentration in a range of approximately 5*10¹⁹ cm⁻³ to approximately 5*10²⁰ cm⁻³. The sheet resistance in the lightly doped regions having the same conduction type lies in a range of approximately 60 ohms/sq to approximately 300 ohms/sq, for example in a range of approximately 80 ohms/sq to approximately 200 ohms/sq, for example in a range of approximately 100 ohms/sq to approximately 150 ohms/sq.

In 308, diffusion is effected in a high-temperature furnace. The diffusion may be carried out for example at a temperature in a range of approximately 700° C. to approximately 1000° C., for example in a range of approximately 750° C. to approximately 950° C., for example in a range of approximately 800° C. to approximately 900° C., for example for a time duration in a range of approximately 3 minutes to approximately 120 minutes, for example in a range of approximately 10 minutes to approximately 60 minutes, for example in a range of approximately 15 minutes to approximately 45 minutes.

Subsequently, in 310, a phosphorus glass etch may be carried out in order to remove the phosphorus glass (for example phosphosilicate glass (PSG)), that has been formed in the context of the diffusion in the high-temperature furnace.

In 312, an antireflection layer (for example composed of silicon nitride or some other suitable material) may then be applied, for example by means of a CVD method, for example by means of a plasma-enhanced (PE) CVD method (PE-CVD), or by means of a PVD method, such as e.g. by means of sputtering.

In 314, on the rear side and the front side of the solar cell substrate, metal contacts (also designated as metal fingers) are formed, for example by means of the screen printing of a suitable metal-containing (for example silver-containing or aluminum-containing) paste, and the paste, and thus the metal, for example, is impressed into the through-holes. A contact firing step is used to fire the paste and thus the metal through the antireflection layer formed previously, whereby an electrical contact with the semiconductor surface (for example silicon surface) of the solar cell substrate is formed.

Illustratively, in 314, therefore, the first metal contact or contacts are formed on the front side of the solar cell substrate through the through-holes to a first busbar on the rear side of the solar cell substrate.

Finally, in 316, in this implementation, the regions doped with the first conduction type (for example n-doped) are isolated, to put it another way electrically insulated, from the regions doped with the second conduction type (for example p-doped), for example by one laser trench or a plurality of laser trenches being formed. Illustratively, in 316, therefore, the second metal contact or contacts are produced on the rear side of the solar cell substrate.

It should be pointed out that in various implementations, selectively spraying on the phosphoric acid droplets with different droplet densities may optionally be restricted to the front side.

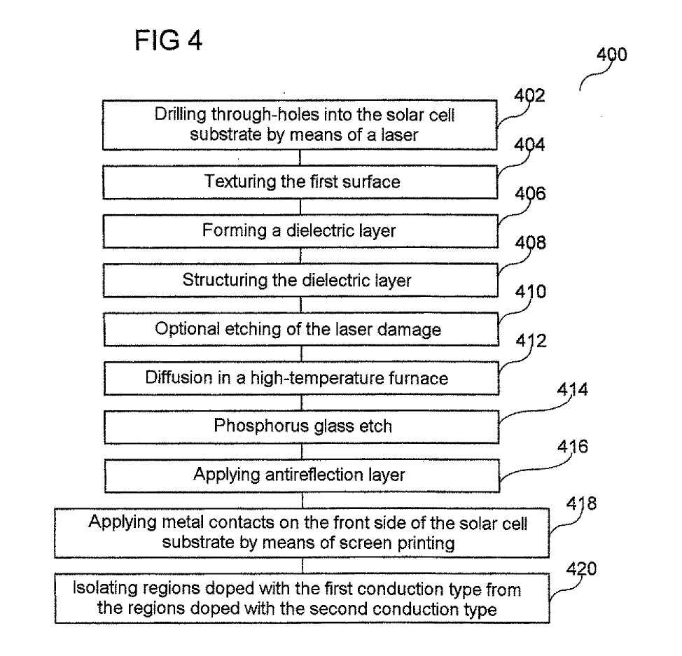

FIG. 4 shows a flowchart 400 illustrating a method for producing a solar cell in accordance with another implementation of various embodiments.

In contrast to the implementation illustrated in FIG. 2, in the implementation illustrated in FIG. 4 and explained below for the processing of the selective emitter, a partly permeable diffusion mask, for example composed of silicon oxide (e.g. SiO₂), is applied. Said mask may firstly either be thermally oxidized or deposited by means of a plasma process over the whole area. Subsequently, said mask is selectively opened in the region of the contact fingers and the through-holes by means of a laser process. During subsequent diffusion, the desired selective emitter forms. Afterward, the diffusion mask may be removed wet-chemically.

In various exemplary embodiments, the thickness of the partly permeable diffusion mask may be less than or equal to 200 nm, for example less than or equal to 175 nm, for example less than or equal to 150 nm, for example less than or equal to 125 nm, for example less than or equal to 100 nm.

In detail, the process sequence in accordance with this implementation includes, for example:

In 402, for example by means of a laser, through-holes are drilled into the solar cell substrate (wherein metal contact fingers may already have been formed onto the solar cell substrate). In an alternative configuration, the through-holes may be formed by means of an etching process, alternatively or additionally by means of a laser.

Furthermore, in an optional process in 404 the surface, for example the emitter side surface (to put it another way the sun side of the solar cell to be formed), may be textured, for example by means of anisotropic etching in an alkaline solution or by means of etching in an acidic solution or by means of sawing V-trenches into the solar cell substrate on the first surface.

In 406, a dielectric layer (for example composed of silicon oxide (SiOₓ, e.g. SiO₂, or silicon nitride (SiNₓ, e.g. Si₃N₄)) may be formed. The dielectric layer may be formed by means of thermal oxidation or by means of deposition, for example using a CVD method or sputtering. The thickness of the dielectric layer may be chosen or be such that the dielectric layer partly impedes the diffusion of the dopant in a subsequent diffusion step.

Afterward, in 408, the dielectric layer may be structured, for example by means of a laser. The mask, i.e. the dielectric layer, is removed at the subsequently highly doped locations.

Then, in 410, in an optional process step, the laser damage may be etched away.

In 412, diffusion is effected in a high-temperature furnace. The diffusion may be carried out for example at a temperature in a range of approximately 750° C. to approximately 1050° C., for example in a range of approximately 800° C. to approximately 1000° C., for example in a range of approximately 850° C. to approximately 950° C., from approximately 3 minutes to approximately 120 minutes, for example in a range of approximately 10 minutes to approximately 60 minutes, for example in a range of approximately 15 minutes to approximately 45 minutes.

Subsequently, in 414, a phosphorus glass etch may be carried out in order to remove the phosphorus glass (for example phosphosilicate glass (PSG)), that has been formed in the context of the diffusion in the high-temperature furnace.

In 416, an antireflection layer (for example composed of silicon nitride or some other suitable material) may then be applied, for example by means of a CVD method, for example by means of a plasma-enhanced (PE) CVD method (PE-CVD), or by means of a PVD method, such as e.g. by means of sputtering.

In 418, on the rear side and the front side of the solar cell substrate, metal contacts (also designated as metal fingers) are formed, for example by means of the screen printing of a suitable metal-containing (for example silver-containing or aluminum-containing) paste, and the paste, and thus the metal, for example, is impressed into the through-holes. A contact firing step is used to fire the paste and thus the metal through the antireflection layer formed previously, whereby an electrical contact with the semiconductor surface (for example silicon surface) of the solar cell substrate is formed. Illustratively, in 418, therefore, the first metal contact or contacts are formed on the front side of the solar cell substrate through the through-holes to a first busbar on the rear side of the solar cell substrate.

Finally, in 420, in this implementation, the regions doped with the first conduction type (for example n-doped) are isolated, to put it another way electrically insulated, from the regions doped with the second conduction type (for example p-doped), for example by one laser trench or a plurality of laser trenches being formed. Illustratively, in 420, therefore, the second metal contact or contacts are produced on the rear side of the solar cell substrate.

In contrast to the implementation illustrated in FIG. 4, in a different implementation, the partly permeable diffusion mask may be produced by means of a CVD method or by means of the sputtering of a silicon oxide film or a silicon nitride film through a mask. The mask is applied for example before the deposition on the wafer, e.g. by screen printing, and is removed wet-chemically after the deposition. Alternatively, it is also possible to perform the deposition through a metal mask positioned between the deposition source and the silicon surface.

In contrast to the implementation illustrated in FIG. 4, in yet another implementation, the selective structure of a doped glass may be produced by means of a CVD method through a mask. The mask may be removed wet-chemically after the deposition. In this etching step, the doped glass is not attacked. In the subsequent phosphorus diffusion, the selective emitter structure arises as a result of additional drive-in of the dopant from the glass. The remaining glass may be removed wet-chemically after the diffusion.

The described technologies for producing a selective emitter may also be used in a process sequence for an MWT-PERC solar cell (PERC: Passivated Emitter and Rear Cell) in accordance with alternative implementations.

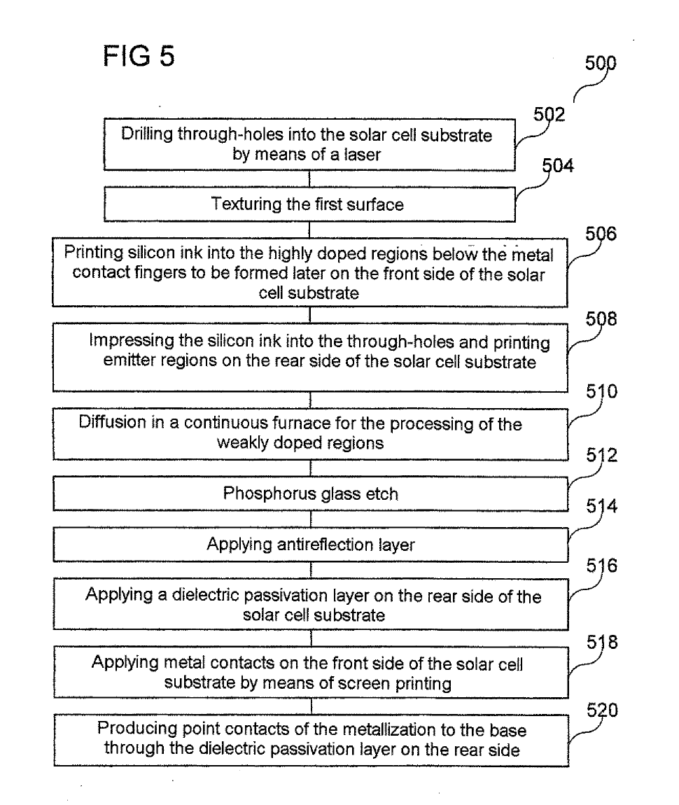

FIG. 5 shows a flowchart 500 illustrating a method for producing a solar cell in accordance with another implementation of various embodiments, wherein an MWT-PERC solar cell is provided.

When using the doped silicon ink in accordance with the implementation illustrated in FIG. 2, the following detailed process sequence is provided in one implementation:

In 502, for example by means of a laser, through-holes are drilled into the solar cell substrate (wherein metal contact fingers may already have been formed onto the solar cell substrate). In an alternative configuration, the through-holes may be formed by means of an etching process, alternatively or additionally by means of a laser.

Furthermore, in an optional process in 504 the surface, for example the emitter side surface (to put it another way the sun side of the solar cell to be formed), may be textured, for example by means of anisotropic etching in an alkaline solution or by means of etching in an acidic solution or by means of sawing V-trenches into the solar cell substrate on the first surface.

Subsequently, in 506, doped (typically doped with phosphorus silicon ink may be printed into the highly doped regions below the metal contact fingers to be formed later on the front side (i.e. the first surface) of the solar cell substrate. The silicon ink may be doped for example with phosphorus with a doping concentration in a range of approximately 10¹⁸ cm⁻³ to approximately 10²² cm⁻³, for example with a doping concentration in a range of approximately 10¹⁹ cm⁻³ to approximately 5*10²¹ cm⁻³, for example with a doping concentration in a range of approximately 10²⁰ cm⁻³ to approximately 10²¹ cm⁻³.

Furthermore, in 508, the silicon ink may be impressed into the through-holes and it may also be printed onto the emitter regions of the rear side (i.e. of the second surface of the solar cell substrate) which have been or are electrically coupled to the silicon ink in the through-holes, such that an electrically conductive connection is formed between the emitter region on the emitter side of the solar cell substrate and the emitter regions on the rear side. Alternatively, it is possible to print these regions of the rear side by means of a suitable paste, for example a phosphorus-containing paste.

In 510, single-sided diffusion on the front side in a continuous furnace for the processing of the weakly doped regions may be provided. The diffusion may be carried out for example at a temperature in a range of approximately 700° C. to approximately 1000° C., for example in a range of approximately 750° C. to approximately 950° C., for example in a range of approximately 800° C. to approximately 900° C., for example for a time duration in a range of approximately 3 minutes to approximately 120 minutes, for example in a range of approximately 10 minutes to approximately 60 minutes, for example in a range of approximately 15 minutes to approximately 45 minutes.

Subsequently, in 512, a phosphorus glass etch may be carried out in order to remove the phosphorus glass (for example phosphosilicate glass (PSG)), that has been formed in the context of the diffusion from the paste.

In 514, an antireflection layer (for example composed of silicon nitride or some other suitable material) may then be applied, for example by means of a CVD method, for example by means of a plasma-enhanced (PE) CVD method (PE-CVD), or by means of a PVD method, such as e.g. by means of sputtering.

In 516, a direct passivation layer may be applied on the rear side of the solar cell substrate. In various implementations, the dielectric passivation layer may have a layer thickness in a range of approximately 20 nm to approximately 300 nm, for example a layer thickness in a range of approximately 50 nm to approximately 200 nm, for example a layer thickness in a range of approximately 70 nm to approximately 150 nm.

In 516, on the rear side and the front side of the solar cell substrate, metal contacts (also designated as metal fingers) are then formed, for example by means of the screen printing of a suitable metal-containing (for example silver-containing or aluminum-containing) paste, and the paste, and thus the metal, for example, is impressed into the through-holes. A contact firing step is used to fire the paste and thus the metal through the antireflection layer on the front side and optionally through the passivation layer on the emitter regions of the rear side formed previously, whereby an electrical contact with the semiconductor surface (for example silicon surface) of the solar cell substrate is formed.

Finally, in 520, in this implementation, point contacts of the metallization to the base of the solar cell are produced through the dielectric passivation layer on the rear side, e.g. by means of a laser process.

It should be pointed out that in various implementations, printing the doped silicon ink may optionally be restricted to the front side.

In the same way, in another implementation, it is also possible to use the process sequence of the implementation illustrated in FIG. 3 for producing an MWT-PERC solar cell.

In various exemplary embodiments, a method for producing a solar cell (and a solar cell produced in accordance with this method) is provided, including the following: producing through-holes into the wafer; etching the through-holes; regionally diffusing a dopant into the wafer surface for forming a selective emitter; and forming first metallic contacts on the light incidence side of the wafer, in the through-holes and onto the rear side of the wafer in a first region and forming second metallic contacts on the rear side of the wafer in a second region.

In one configuration, the selective emitter may be produced by the regional application of a dopant and subsequent heat treatment.

In another configuration, phosphoric acid may be used as the dopant.

In yet another configuration, the selective emitter may be produced by printing a structure composed of doped silicon ink.

In yet another configuration, the selective emitter may be produced by producing a partly permeable selective diffusion mask and its subsequent diffusion step.

In yet another configuration, the selective emitter may be produced by applying a selective structure composed of doped glass and subsequent diffusion.

In another configuration, a CVD deposition step may be used.

In another configuration, the selective emitter may be produced on the light incidence side and in the through-holes.

In another configuration, the selective emitter may be produced on the light incidence side, in the through-holes and on the rear side.

In various exemplary embodiments, a solar module is provided, including a plurality of solar cells, wherein one solar cell or a plurality of solar cells of the solar module may have been produced in accordance with one exemplary embodiment. At least some solar cells arranged in an adjacent fashion are electrically connected to one another by means of electrically conductive contact wires or contact ribbons or contact tracks.

The contact wires for electrically connecting two solar cells may be connected to the emitter contact on the rear side of a first solar cell of in each case two mutually adjacent solar cells and to the base contact on the rear side of a second solar cell of in each case two mutually adjacent solar cells.

In various exemplary embodiments, a method for producing a solar cell is provided. In accordance with the method, through-holes may be formed in a solar cell substrate having the basic doping of a first conduction type. Furthermore, predetermined surface regions of a first surface of the solar cell substrate which include at least one portion of the through-holes may be highly doped with a second, opposite conduction type; and simultaneously or subsequently other surface regions of the first surface are lightly doped with the second conduction type. Furthermore, first metallic contacts may subsequently be formed at least in one portion of the predetermined regions in at least one portion of the through-holes and in first regions of a second surface of the solar cell substrate, which lies opposite the first surface of the solar cell substrate. Finally, second metallic contacts may be formed in second regions on the second surface in such a way that the second metallic contacts are electrically isolated from the first metallic contacts.

Illustratively, in various embodiments, a Metal Wrap Through (MWT) solar cell having a selective emitter (MWT-SE) is provided. The MWT-SE solar cell illustratively combines the advantages both of the conventional MWT solar cell and of the conventional SE solar cell. By virtue of the omission of the busbars on the front side, a higher current is generated than in the case of conventional interconnection, and the selective emitter reduces recombination losses and losses through contact resistances, and the rear-side interconnection of the solar cells minimizes losses in the module. In this case, in various embodiments, the selective emitter is processed in such a way that there is no intermediate product with a homogeneous emitter in the process for producing the solar cell. Illustratively, therefore, proceeding from a solar cell substrate having a basic doping, the selective emitter is formed directly, without a homogeneous emitter being formed in any intermediate step of the production process.

In various embodiments, the process of forming the selective emitter may be restricted to the front side of the solar cell substrate or else relate to the doping in the holes and on the rear side of the solar cell substrate.

In various embodiments, a solar cell should be understood to mean a device which directly converts light energy (for example at least part of the light in the visible wavelength range of from approximately 300 nm to approximately 1150 nm, for example sunlight) into electrical energy by means of the so-called photovoltaic effect.

Various embodiments relate to crystalline semiconductor substrates as solar cell substrates, for example composed of silicon.

In one configuration, the through-holes may be formed by means of an etching process, alternatively or additionally by means of a laser.

Furthermore, the predetermined regions may be doped by regional application of a dopant.

In various developments, phosphoric acid may be used as a dopant.

In yet another configuration, the predetermined regions may be highly doped by a doped silicon ink being printed in the predetermined regions; and the remaining regions of the first surface may subsequently be lightly doped by a gas containing dopant acting on the solar cell substrate with thermal treatment.

Furthermore, the predetermined regions may be highly doped by a liquid containing dopant being applied by spraying methods in these regions with a first quantity, and the remaining regions of the first surface may be lightly doped by said liquid being applied with a second quantity, which is smaller than the first quantity. Simultaneously or subsequently a thermal treatment of the solar cell substrate may be effected.

In yet another configuration, the liquid may contain a wetting agent, which supports a doping of the through-holes during the doping of the predetermined regions.

Furthermore, a partly permeable diffusion mask may be formed on the first surface of the solar cell substrate, and this diffusion mask may subsequently be opened in accordance with the predetermined regions. Furthermore, a gas containing dopant may subsequently act on the solar cell substrate with thermal treatment in such a way that a high doping is effected in the predetermined regions and a low doping is effected in the remaining regions of the first surface.

In accordance with yet another development of the method, the partly permeable diffusion mask may include silicon oxide and/or silicon nitride.

The partly permeable diffusion mask may be deposited on the first surface of the solar cell substrate, for example by means of a deposition method from the gas phase (Chemical Vapor Deposition, CVD).

In one configuration, the partly permeable diffusion mask may be formed on the first surface of the solar cell substrate by means of thermal oxidation.

In a further configuration, the partly permeable diffusion mask may be applied by a PVD method, e.g. by sputtering.

Furthermore, the diffusion mask may be opened in the predetermined regions by means of a laser beam.

In accordance with one development, an etching mask may be arranged on the diffusion mask by means of screen printing, wherein the diffusion mask may be opened in the predetermined regions by means of an etching method.

In accordance with yet another development, the thickness of the partly permeable diffusion mask may be less than or equal to 200 nm, for example less than or equal to 175 nm, for example less than or equal to 150 nm, for example less than or equal to 125 nm, for example less than or equal to 100 nm.

In accordance with yet another development, the selective emitter may additionally be formed in at least one portion of the through-holes.

Furthermore, the selective emitter may additionally be formed in at least one portion of a surface region of the solar cell substrate on the second surface.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for producing a solar cell,
wherein through-holes are formed in a solar cell substrate having the basic doping of a first conduction type;
wherein predetermined surface regions of a first surface of the solar cell substrate which include at least one portion of the through-holes are highly doped with a second, opposite conduction type; and simultaneously or subsequently other surface regions of the first surface are lightly doped with the second conduction type;
wherein first metallic contacts are subsequently formed at least in one portion of the predetermined regions in at least one portion of the through-holes and in first regions of a second surface of the solar cell substrate, which lies opposite the first surface of the solar cell substrate;
wherein second metallic contacts are formed in second regions on the second surface in such a way that the second metallic contacts are electrically isolated from the first metallic contacts;
wherein the predetermined regions are highly doped by a doped silicon ink being printed in the predetermined regions; and
wherein the remaining regions of the first surface are subsequently lightly doped by a gas comprising dopant acting on the solar cell substrate with thermal treatment.

2. The method as claimed in claim 1,
wherein the through-holes are formed by means of an etching process.

3. The method as claimed in claim 1,
wherein the through-holes are formed by means of a laser.

4. The method as claimed in claim 1,
wherein the predetermined regions are doped by regional application of a dopant.

5. A method for producing a solar cell,
wherein through-holes are formed in a solar cell substrate having the basic doping of a first conduction type;
wherein predetermined surface regions of a first surface of the solar cell substrate which include at least one portion of the through-holes are highly doped with a second, opposite conduction type; and simultaneously or subsequently other surface regions of the first surface are lightly doped with the second conduction type;
wherein first metallic contacts are subsequently formed at least in one portion of the predetermined regions in at least one portion of the through-holes and in first regions of a second surface of the solar cell substrate, which lies opposite the first surface of the solar cell substrate;
wherein second metallic contacts are formed in second regions on the second surface in such a way that the second metallic contacts are electrically isolated from the first metallic contacts;
wherein the predetermined regions are highly doped by a liquid comprising dopant being applied by spraying methods in these regions with a first quantity, and the remaining regions of the first surface are lightly doped by said liquid being applied with a second quantity, which is smaller than the first quantity; and
wherein simultaneously or subsequently a thermal treatment of the solar cell substrate is effected.

6. The method as claimed in claim 5,
wherein the liquid contains a wetting agent, which supports a doping of the through-holes during the doping of the predetermined regions.

7. The method as claimed in claim 5,
wherein the through-holes are formed by means of an etching process.

8. The method as claimed in claim 5,
wherein the through-holes are formed by means of a laser.

9. The method as claimed in claim 5,
wherein the predetermined regions are doped by regional application of a dopant.

10. A method for producing a solar cell,
wherein through-holes are formed in a solar cell substrate having the basic doping of a first conduction type;
wherein predetermined surface regions of a first surface of the solar cell substrate which include at least one portion of the through-holes are highly doped with a second, opposite conduction type; and simultaneously or subsequently other surface regions of the first surface are lightly doped with the second conduction type;
wherein first metallic contacts are subsequently formed at least in one portion of the predetermined regions in at least one portion of the through-holes and in first regions of a second surface of the solar cell substrate, which lies opposite the first surface of the solar cell substrate;
wherein second metallic contacts are formed in second regions on the second surface in such a way that the second metallic contacts are electrically isolated from the first metallic contacts;
wherein a partly permeable diffusion mask is formed on the first surface of the solar cell substrate;
wherein said diffusion mask is subsequently opened in accordance with the predetermined regions; and
wherein subsequently a gas comprising dopant acts on the solar cell substrate with thermal treatment in such a way that a high doping is effected in the predetermined regions and a low doping is effected in the remaining regions of the first surface.

11. The method as claimed in claim 10,
wherein the partly permeable diffusion mask comprises at least one of silicon oxide and silicon nitride.

12. The method as claimed in claim 10,
wherein the partly permeable diffusion mask is deposited on the first surface of the solar cell substrate.

13. The method as claimed in claim 12,
wherein the partly permeable diffusion mask is deposited on the first surface of the solar cell substrate by means of a deposition method from the gas phase or by means of sputtering.

14. The method as claimed in claim 10,
wherein the partly permeable diffusion mask is formed on the first surface of the solar cell substrate by means of thermal oxidation.

15. The method as claimed in claim 10,
wherein the diffusion mask is opened in the predetermined regions by means of a laser beam.

16. The method as claimed in claim 10,
wherein an etching mask is arranged on the diffusion mask by means of screen printing; and
wherein the diffusion mask is opened in the predetermined regions by means of an etching method.

17. The method as claimed in claim 10,
wherein the thickness of the partly permeable diffusion mask is less than or equal to 200 nm.

18. The method as claimed in claim 10,
wherein the through-holes are formed by means of an etching process.

19. The method as claimed in claim 10,
wherein the through-holes are formed by means of a laser.

20. The method as claimed in claim 10,
wherein the predetermined regions are doped by regional application of a dopant.
